(19) United States
(12) Patent Application Publication
(10) Pub. No.: US 2003/0117782 A1
(43) Pub. Date: Jun. 26, 2003

(54) Electronic circuits

(76) Inventors: Sean Conor Wrycraft, Harrow (GB); Brian Benstead, Farnham (GB)

Correspondence Address: B. Noel Kivlin, Conley, Rose, & Tayon, P.C., P.O. Box 398, Austin, TX, 78767, US

(21) Appl. No.: 10/291,199

(22) Filed: Nov. 8, 2002

(30) Foreign Application Priority Data
Jun. 10, 2002 (GB) 0213249.6
Nov. 30, 2001 (GB) 0128777.0
Nov. 8, 2001 (GB) 0126882.0

(51) Int. Cl. H05K 5/00; H05K 5/04; H05K 5/06

(52) U.S. Cl. 361/752

(57) ABSTRACT

A modular electronic circuit is described wherein mother and daughterboards are arranged in perpendicular planes extending from front to rear within the modules. Ventilation openings in the front and rear faces, and one or more ventilation units mounted to the front and/or rear faces, provide a substantially rectilinear airflow through the module. The absence of transverse vertical barriers to airflow enables a more efficient use of the internal volume of the module for electronic circuitry and reduces fan power requirement and noise generation.

### BACKGROUND OF THE INVENTION

The present invention relates to electronic equipment, and is primarily concerned with modular rack-mounted electronic circuits such as server computers. Specifically, the invention is concerned with circuit board arrangements which provide for maximum density of circuitry components in an electronics module while permitting adequate cooling ventilation of the circuits.

Such circuits will typically be contained in casings mountable in, for example, nineteen inch racks, or other size racks such as twenty-three inch or metric racks. The circuits may for instance be employed as servers for a number of systems, for example in local area networks (LANs), wide area networks (WANs), telecommunications systems or other operations such as database management or as internet servers.

In rack-mounted modular electronics, circuits are typically constructed from one or more circuit modules, each comprising a casing containing a motherboard and a number of daughter boards arranged in planes perpendicular to the motherboard and connected to the motherboard by edge connectors. The motherboard may have some processing or other capability, but equally the motherboard may simply serve to provide electrical connection between a number of daughter boards and the other components of the module. It has become customary to mount a plurality of circuit modules in a columnar array within a rack. Several racks may be placed side-by-side, so that horizontal rows of modules, called “shelves” are formed. In such an array, access to the modules is available only via the front and rear faces. When a daughter board is to be removed, therefore, it is removed through the front or rear face of the module in a horizontal direction.

To enable such a daughter board to be easily connectable to the motherboard by movement of the daughter board in the horizontal direction, the motherboard is arranged in a vertical plane or “backplane” extending across the rear of the module, and the daughter boards are arranged either in horizontal planes, or in vertical planes extending from front to rear in the module.

Cooling of the components on the daughter boards is effected by blowing air into the module, typically through the front face of the module, so that the air passes over the daughter boards and exits from the rear of the module after being deflected vertically round the motherboard. This requirement for vertical movement of air round the motherboard increases the height of the module beyond that necessary to accommodate the circuit boards, due to the need for an internal headspace where no components may be mounted. The serpentine airflow path increases the power requirement for moving the air, leading to increased noise levels from the cooling fans.

### SUMMARY OF THE INVENTION

An aspect of the present invention provides a circuit module for a rack-mounted circuit wherein the module has a casing with front and rear faces, upper and lower faces, and side faces supportable on a rack structure for horizontal movement relative to the rack structure in the front and rear directions, the casing containing a motherboard to which a number of daughter boards are connectable, and wherein the motherboard is mounted in a plane extending from front to rear in the module.

In one embodiment, the motherboard is in a horizontal plane and the daughter boards are arranged in vertical planes extending from front to rear in the module. The horizontal plane may be at the top or the bottom of the module, with daughter boards mounted for insertion through openings in the lower or upper surfaces of the module, respectively. In another alternative, the horizontal plane may be intermediate the height of the module, with daughter boards mounted for insertion through openings in both the lower and upper surfaces of the module. When the daughter boards are mounted in vertical planes, guides may be provided to assist in the insertion and removal of the daughter boards. The guides may be provided with movement control elements to engage the daughter boards during insertion and/or removal to prevent free-falling of the daughter boards into or out of the module, should the operative lose his or her grip on the daughter board. Such devices are described in copending UK patent application 0128777.0 of the present applicant.

In another embodiment, the motherboard is in a vertical plane and the daughter boards are arranged in horizontal planes extending from front to rear in the module. The vertical plane may be at one side of the module, with daughter boards mounted for insertion through openings in the other side surface of the module. In another alternative, the vertical plane may be intermediate the width of the module, with daughter boards mounted for insertion through openings in both of the side surfaces of the module.

In the modules of the above described embodiments, cooling units such as fans may be mounted to the front and/or rear faces of the module to cause a horizontal airflow through the module to cool the components on the daughter boards, without the airflow needing to be diverted vertically round the backplane to exit the module. No internal headspace is thus required, and the height of the module may thus be reduced to provide a more efficient use of the internal volume of the module. The substantially rectilinear airflow path through the module reduces the fan power requirement and thus also reduces fan noise.

In the foregoing, references to “vertical” and “horizontal” refer to the module in its mounted position in a rack structure.

The modules may be mounted to the rack structure by means of drawer runners or other supports which enable the modules to be moved horizontally out of the rack to afford access to the upper, lower, and side surfaces of the modules as necessary.

Another aspect of the invention provides an electrical circuit comprising a rack and one or more circuit modules, wherein the or a or each module has a casing with front and rear faces, upper and lower faces, and side faces supportable on the rack structure for horizontal movement relative to the rack structure in the front and rear directions, the casing containing a motherboard to which a number of daughter boards are connectable, and wherein the motherboard is mounted in a plane extending from front to rear in the module. The motherboard may be in a vertical or a horizontal plane, with the daughter boards mountable in horizontal or vertical planes, respectively.

A yet further aspect of the invention provides for a method of removing a daughter board from a module of such a circuit, comprising the steps of:

drawing the module forwardly or rearwardly of the rack;

removing a daughter board by moving the daughter board in its plane in a direction substantially perpendicularly away from the motherboard and out of the module.

In embodiments where the motherboard is mounted in the module in a vertical plane extending from front to rear in the module, the daughter board is removed horizontally through a side of the module.

In embodiments where the motherboard is mounted in the module in a horizontal plane extending from front to rear in the module, the daughter board is removed vertically through the upper or lower face of the module.

### BRIEF DESCRIPTION OF THE DRAWINGS

Embodiments of the present invention will now be described in detail with reference to the accompanying drawings, in which corresponding parts are given like reference numbers. In the drawings:

FIG. 1 is a cutaway perspective view of a conventional electronics module;

FIG. 2 is a schematic vertical sectional view of the module of FIG. 1;

FIG. 3 is a cutaway perspective view of a module in a first embodiment of the invention.

FIG. 4 is a schematic vertical sectional view of the module of FIG. 3;

FIG. 5 is a perspective view of a rack containing three modules;

FIG. 6 is a cutaway perspective view of a module in a second embodiment of the invention; and

FIG. 7 is a schematic vertical sectional view of the module of FIG. 6.

### DESCRIPTION OF PARTICULAR EMBODIMENTS

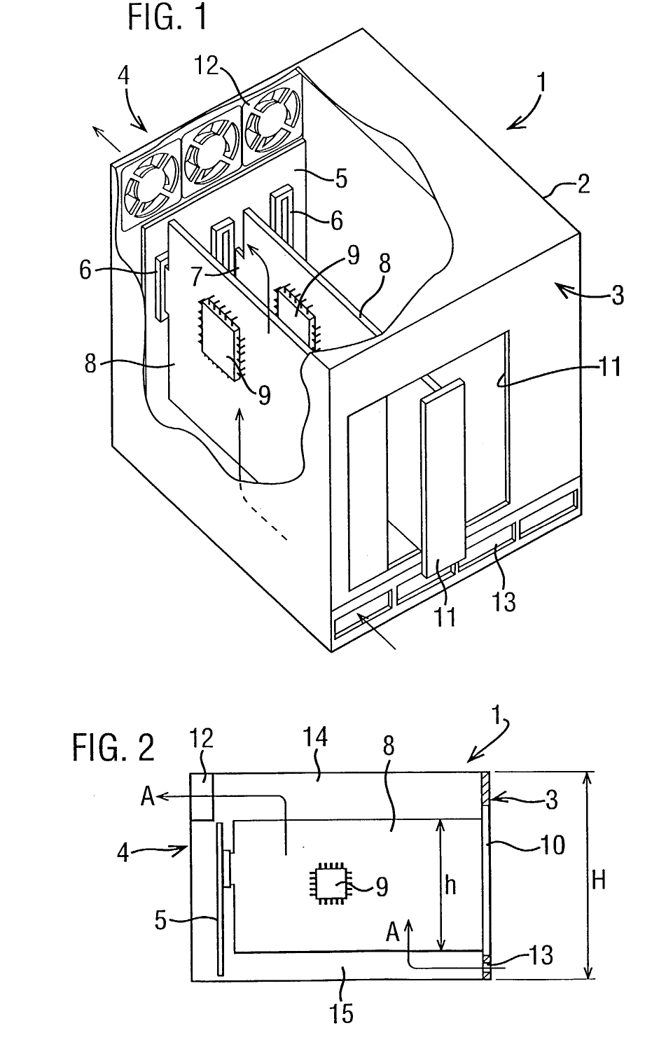

Referring now to the drawings, in which like reference numerals are used to designate corresponding elements, FIGS. 1 and 2 are perspective and sectional views, of a typical electronics module 1 having a housing 2 with a front face 3 and a rear face 4.

A motherboard 5 is mounted in a vertical plane extending across the width of the module 1 adjacent a lower part of the rear face 4 of the housing 2. The motherboard 5 is provided with edge connectors 6 into which edge portions 7 of daughter boards 8 may be engaged.

The daughter boards 8 extend in vertical planes from the front face 3 of the housing 2 to the motherboard 5, and carry electronics components 9 for performing circuit functions. Examples of components 9 are processors, memory components or other components of a computer such as a server computer. The components 9 should not be considered as being limited to the foregoing examples.

On their vertical edges opposite the edge portions 7, the daughter boards 8 have grip portions 10 for inserting and removing the daughter boards 8 through an opening 11 in the front face 3 of the housing 2.

At the upper part of the rear face 4 of the housing 2, a number of fans 12 are mounted to extract air from within the housing 2 through the rear face 4. At the lower part of the front face 3, a number of air intake openings 13 are provided.

As is clear from FIG. 2, when the fans 12 are in operation air is drawn from a head space 14 within the housing 2 above the daughter boards 8 and is expelled through the fans 12. This air in the head space 14 is replaced by air moving vertically upwardly past the daughter boards 9, having entered the housing 2 through the air intake openings 13 in the lower part of the front face 3. The air flow is shown by arrows A in FIG. 2. In order to provide this air flow, not only is it necessary to have a clear head space 14 above the daughter boards 8, but it is also convenient to provide a plenum space 15 below the daughter boards 8 to allow air to penetrate towards the rear of the daughter boards before moving vertically upwards.

As is readily appreciable from FIG. 2, the overall height H of the module 1 exceeds the height h of the daughter boards 8 by the combined vertical extents of the head space 14 and plenum space 15. The internal volume of the module 1 is therefore considerably greater than the volume of the electronics package contained by it. Furthermore, the serpentine nature of the airflow path increases the resistance to flow of the air, resulting in the need for higher fan motor power to overcome the pressure drop along the flow path. Higher levels of noise are also generated by the fans.

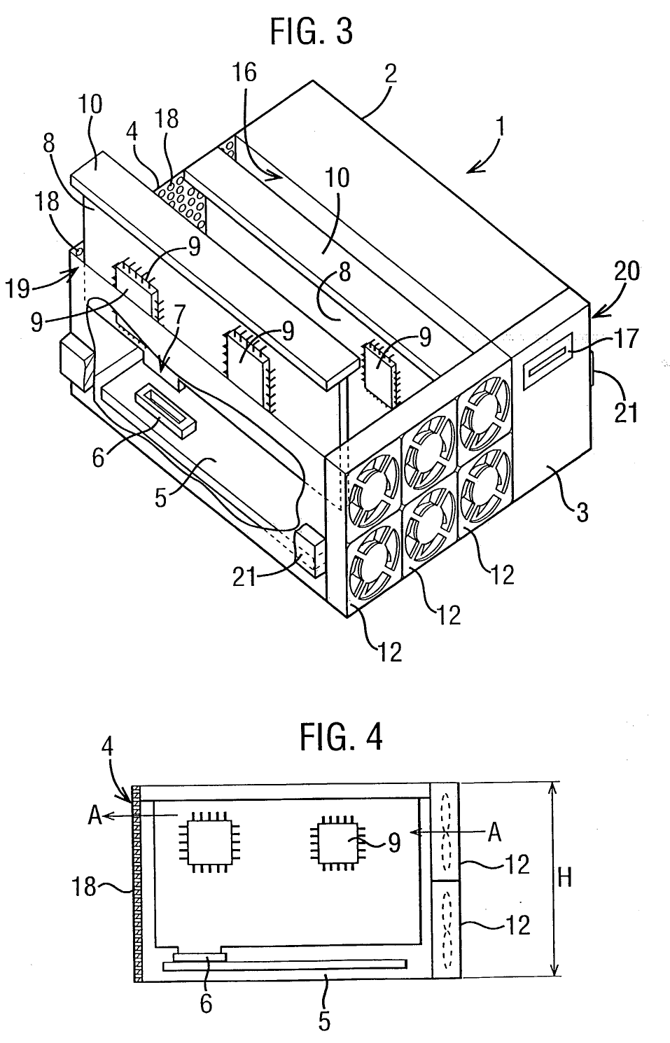

FIGS. 3 and 4 show, in perspective and in vertical sectional view, respectively, a first embodiment of the present invention wherein a more efficient use is made of the internal volume of the module by rearranging the motherboard and daughter boards.

Specifically, in FIG. 3 there is shown a module 1 having a metallic housing 2 with a front face 3 and a rear face 4. A vertical bulkhead 16 extends from the front face 3 to the rear face 4 and divides the housing 2 into two sections. To the right of the bulkhead (as seen in FIG. 3) is an equipment bay in which are housed media drives, such as 17, and other ancillary equipment such as power supplies and I/O interfaces. Since the media drive 17 is to be accessible from the front face of the module, ventilation units may be mounted to the rear face of the equipment bay, or internally in the equipment bay, to cool the ancillary devices. Some devices such as power supplies are conventionally provided with dedicated cooling fans. The walls and bulkhead of the module are conveniently formed from sheet metal by conventional fabrication techniques such as pressing, rivetting, welding, etc.

To the left of the bulkhead 16 is an electronics bay, in which a motherboard 5 is mounted in a horizontal plane extending across the bottom of the electronics bay. Edge connectors 6 are provided as before on the motherboard 5, to connect to daughter boards 8 arranged in vertical planes extending from the front face 3 of the housing 2 to the rear face 4. The daughter boards 8 are inserted through the open top of the electronics bay, so that edge portions 7 of the daughter boards 8 engage with edge connectors 6 of the motherboard 5. Grip portions 10 of the daughter boards 8 may be provided with handles, and/or latching means to secure the grip portion 10 to the housing 2 when the daughter board 8 is mounted. Vertical guides (not shown) may be provided in the housing 2 to guide the edges of the daughter board 8 as the daughter board 8 is inserted or removed. The guides may be provided with friction devices, one-way clutches, etc to engage the daughter board to prevent free-falling of the daughter boards as they are inserted or removed.

The front face 3 of the module 1 is provided across substantially the entire width and depth of the electronics bay with an array of fans 12 which blow air into the electronics bay from the outside. The rear face 4 of the module 1 is provided with air exit openings 18. In the embodiment shown, a multiplicity of small openings is provided in the rear face 4 of the module 1 to allow air to escape from the electronics bay. A large number, for example 8 or more, of small-diameter fans 12 may be provided, or a smaller number of larger diameter fans may provide adequate air flow.

Side faces 19 and 20 of the housing 2 are provided with runners 21 which enable the module 1 to be mounted in a supporting rack in the manner of a sliding drawer.

As is clear from FIG. 4, by placing the motherboard 5 horizontally within the electronics bay, and by orienting the daughter boards 8 in vertical planes extending between the front face 3 and rear face 4 of the module 1, a substantially entirely horizontal air flow is established through the module 1 when the fans 12 are in operation. Air flow is indicated by the arrows marked A in FIG. 4.

By mounting the motherboard 5 in the horizontal orientation extending from front to back within the module 1, it is no longer necessary to deflect the air vertically round the motherboard as it passes through the module from front to back. Thus, the overall height of the module 1 may be reduced, since there is no longer a need for a head space 14 or plenum space 15 above and below the daughter boards 8. As is seen in FIG. 4, the proportion of the height H of the module which is taken up by daughter boards 8 is increased, leading to a more efficient use of the internal space within the module. Furthermore, the substantially rectilinear airflow path through the module minimises flow resistance due to turning of the flow, and results in lower fan power requirement to establish a given volumetric flow rate. This reduces both electrical consumption of the fans, and noise generation by the fans.

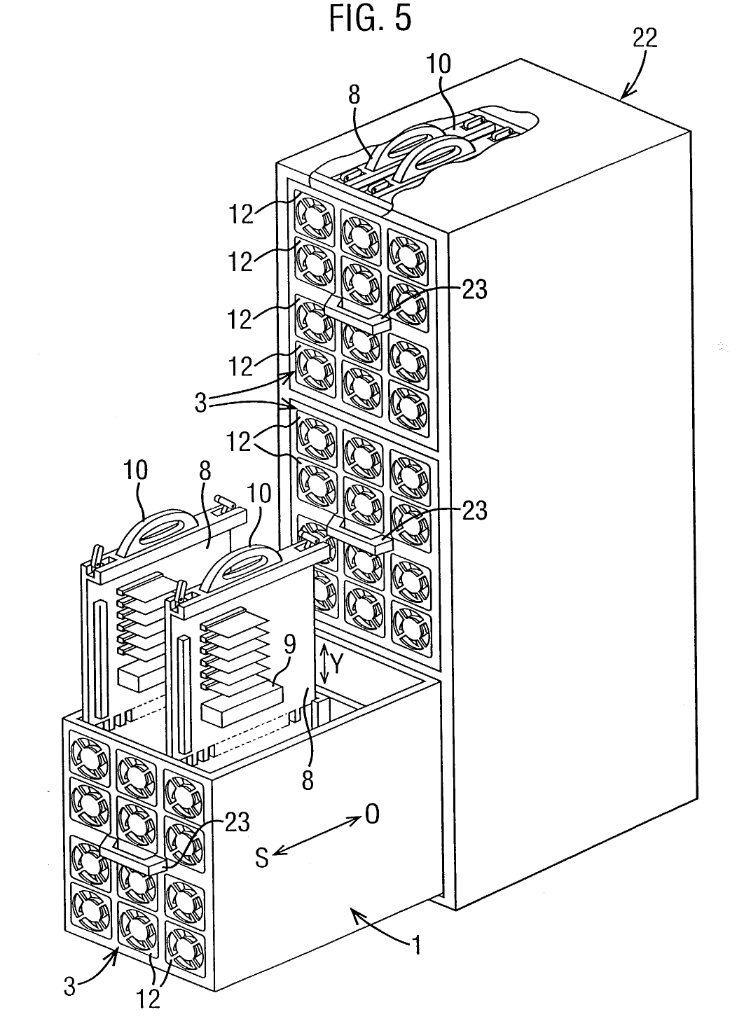

FIG. 5 illustrates an electronic circuit comprising three modules 1 mounted in a supporting structure or rack 22. The modules each have a motherboard arranged horizontally adjacent the lower face of the module, and a number of daughter boards 8 extending in vertical planes between the front face 3 and the rear face 4 of each module. Fan units 12, arranged in arrays substantially entirely covering the front faces of the electronics bays of the modules, provide a substantially horizontal air flow through the modules when in operation.

Each module 1 has a handle 23 on its front face 3, so that a module may be pulled out of the rack 22 in order to access the upper face of the module to withdraw one or more of the daughter boards 8 for replacement or servicing. The upper two modules are shown in the rack in their operating positions.

The lowermost module 1 is seen drawn forward out of the rack into a servicing position, wherein daughter boards may be removed and replaced by lifting them vertically out of the module 1 through an open upper face of the electronics bay. The arrow S-O indicates the direction of movement of the module 1 between the servicing and operating positions. It is to be understood that the servicing position may be in front of the rack, as seen in FIG. 5, or behind the rack with the module 1 being drawn rearwardly out of the rack for servicing.

Two daughter boards 8 are shown withdrawn vertically out of the lowermost module 1 in the direction of arrow V.

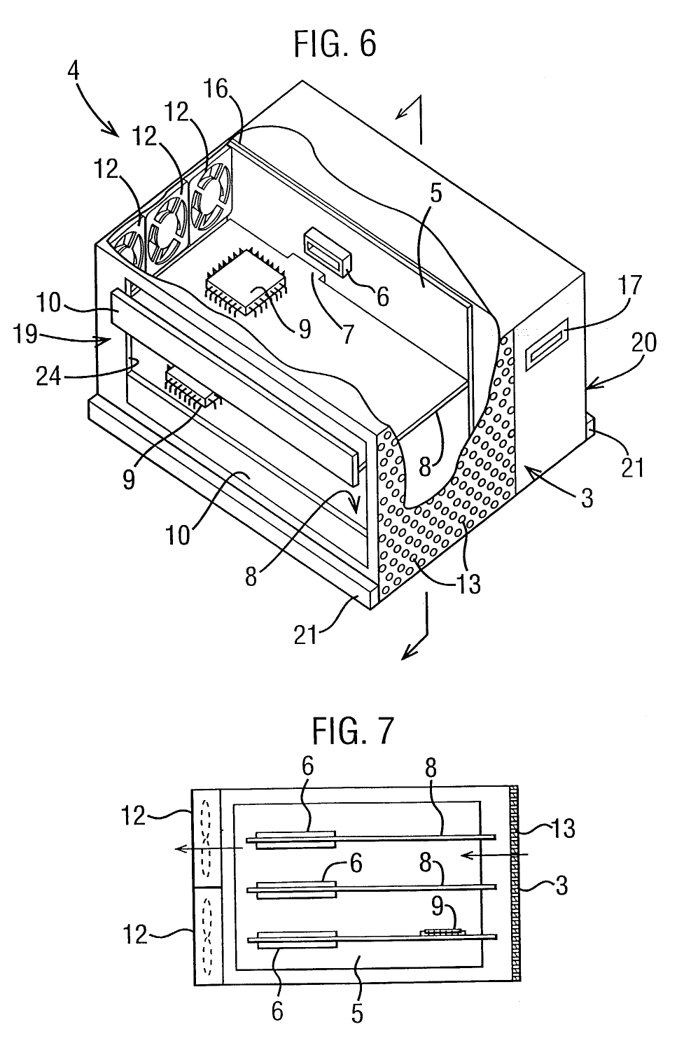

FIGS. 6 and 7 show a further alternative arrangement according to the invention. FIG. 6 is a perspective view of an electronics module and FIG. 7 is a vertical sectional view through the module.

As in FIG. 3, the module is divided into two bays by a vertical bulkhead 16 extending between the front face 3 and the rear face 4. To the right of the bulkhead 16 (as seen in FIG. 6) is an equipment bay containing media drives such as 17, power supplies, etc. The equipment bay may be cooled by ventilation units such as fans mounted externally on the rear face of the module, or by fans mounted internally in the equipment bay. To the left of the bulkhead 16 is an electronics bay, in which a motherboard 5 is mounted in a vertical plane extending between the front face 3 and the rear face 4 of the module, adjacent the bulkhead 16. The motherboard 15 is provided with edge connectors 6 facing away from the bulkhead 16.

The side faces 19 and 20 of the module 1 are provided with runners 21, for mounting the module in a rack 22 such as shown in FIG. 5. In the side face 19, an opening 24 is provided for the ingress and exit of daughter boards 8. Horizontal guides (not shown) may be provided within the module to engage the front and rear edges of the daughter board 8 during insertion and removal. The daughter board 8 is provided, as before, with an edge portion 7 engageable with the edge connectors 6 of the mother board 5. As is seen in FIG. 7, fans 12 mounted adjacent the rear face 4 of the module 1 draw air out of the housing 2. Air intake openings 13 are provided in the front face 3 of the module 1, over substantially the entire area of the electronics bay. In the embodiment shown, a multiplicity of small air intake openings 13 are provided. As an alternative, a smaller number of larger air intake openings may be formed in the front face 3 of the module 1.

It will be appreciated that the fans 12 may be mounted either to the front face 3 or to the rear face 4 of the module 1. It will further be appreciated that the fans 12 may be arranged either to blow cooling air into the interior of the electronics bay, or may be arranged to draw air out of the electronics bay. It is further foreseen that fans 12 may be provided both at the front and rear faces of the module 1, the fans on one face blowing air into the module and the fans on the other face drawing air out of the module. Since the fans are separate from the motherboard and daughter boards, the fans may be removed and replaced without disturbing the mother and daughter boards of the module, and vice versa. This keeps the downtime of the module to a minimum, since the module as a whole may continue to operate while fans or daughter boards are replaced.

When a plurality of small air openings 13 or 18 are provided in the face of the module 1, air can be circulated through the module while the metallic housing of the module maintains an electromagnetic screening of the electronics components within the housing. In an embodiment similar to that shown in FIG. 3, the fans 12 may be mounted to the outside of a foraminous metallic front wall 3 of the housing 2, so as to blow air into the electronics bay through holes in the front wall. The rear wall 4 of the module comprises a metallic wall having a plurality of small air exit openings, and these two perforated walls, in combination with the metallic side walls 19 and 20 and a metallic undersurface for the housing 12 provide electromagnetic protection for the components 9 in the electronics bay. The grip portions 10 of the daughter boards 8 complete the electromagnetic protection of the upper surface, by closing the open upper surface of the electronics bay.

The scope of the present disclosure includes any novel feature or combination of features disclosed herein either explicitly or implicitly or any generalisation thereof irrespective of whether or not it relates to the claimed invention or mitigates any or all of the problems addressed by the present invention. The applicant hereby gives notice that new claims may be formulated to such features during the prosecution of this application or of any such further application derived therefrom. In particular, with reference to the appended claims, features from dependent claims can be combined with those of the independent claims and features from respective independent claims can be combined in any appropriate manner and not merely in the specific combinations enumerated in the claims.

We claim:

1. A modular electronic circuit comprising a rack and a number of electronics modules each having front and rear faces, upper and lower faces and side faces mounted to the rack, in an operating position wherein only the front and rear faces of the module are accessible, the module being movable to a servicing position wherein the upper, lower and side faces are accessible, and wherein at least one module comprises a motherboard mounted within the module in a plane extending from front to back of the module and a number of daughter boards mounted to the motherboard in planes perpendicular to the motherboard and extending from front to back within the module.

2. A circuit according to claim 1, wherein the module is mounted to the rack for movement in the forward and rearward direction relative to the rack between the operating and servicing positions.

3. A circuit according to claim 1, wherein the module is demountable from the rack for movement from the operating to the servicing position.

4. A modular circuit according to claim 1, wherein the motherboard is in a horizontal plane and the daughter board is in a vertical plane.

5. A modular circuit according to claim 1, wherein the motherboard is in a vertical plane and the daughter board is in a horizontal plane.

6. A modular circuit according to claim 1, wherein the side faces of the module are mounted to the rack for movement of the modules in the forward and rearward directions relative to the rack between an operating position wherein only the front and rear faces of the module are accessible, and a servicing position wherein the upper, lower and side faces are accessible.

7. A modular circuit according to claim 1, wherein ventilator units are mounted to the front and/or rear faces of the module, the ventilator units being operable to establish an airflow through the module from the front face to the rear face or vice-versa, parallel to the plane of the motherboard.

8. A modular circuit according to claim 7, wherein the rear and/or front faces respectively are provided with airflow openings.

9. A modular circuit according to claim 1, wherein the airflow openings comprise a multiplicity of perforations in the front and/or rear faces of the module.

10. A modular housing for electronic circuitry comprising a front face, a rear face, a pair of side faces extending between the front and rear faces and an upper and lower face to complete a paralelepipedal enclosure, the housing further comprising:
ventilation openings in the front and rear faces;
first mounting elements for mounting a motherboard within the housing in a plane extending in the direction from the front face to the rear face of the housing;
second mounting elements for mounting at least one daughter board within the housing in a plane perpendicular to the plane of the motherboard and extending in the direction from the front face to the rear face of the housing; and
external support elements on the side faces for attaching the housing to a supporting structure.

11. A housing according to claim 9, further comprising a third mounting element for mounting a ventilator unit to the front or rear face of the housing.

12. A housing according to claim 10, wherein the first mounting element is arranged to support the motherboard in a plane parallel to the upper and lower faces of the housing, and the second mounting elements are arranged to support the daughter board in a plane parallel to the side faces of the housing.

13. A housing according to claim 10, wherein the first mounting element is arranged to support the motherboard in a plane parallel to the side faces of the housing, and the second mounting elements are arranged to support the daughter board in a plane parallel to the upper and lower faces of the housing.

14. A housing according to claim 10, wherein the external support elements comprise sliding runners.

15. A housing according to claim 10, further comprising a bulkhead extending between the front and rear faces of the housing and dividing the interior of the housing into first and second regions, the first mounting element being arranged in said first region.

16. A housing according to claim 15, wherein a third mounting element is adapted to mount a ventilation unit on the front face of the module opposite said first region.

17. A housing according to claim 16 wherein the third mounting element is adapted to mount an array of ventilation units covering substantially the entire area of the front face of the module opposite said first region.

18. A module for an electronic circuit, comprising a housing having front and rear faces with ventilation openings therein, a motherboard and a daughter board electrically connected together and arranged within the housing in perpendicular planes, wherein both the motherboard and the daughter board extend in the direction from the front face of the housing to the rear face.

19. A module according to claim 18, wherein the housing comprises upper and lower surfaces and side surfaces, and the motherboard is in a plane parallel to the upper and lower surfaces.

20. A module according to claim 18, wherein the housing comprises upper and lower surfaces and side surfaces, and the motherboard is in a plane parallel to side surfaces.

21. A module according to claim 18, wherein the module comprises a pair of side surfaces and external support elements on the side surfaces for attaching the module to a support.

22. A module according to claim 21, wherein the external support elements are adapted to permit movement of the module relative to a support, in the direction from front to rear of the module.

23. A module according to claim 18, wherein a ventilation unit is provided on the front or rear face of the module, the ventilation unit being operable to establish an airflow through the front and rear faces of the module and across the motherboard and daughterboard.

24. A module according to claim 23, wherein the ventilation unit is mounted to the outside of the front or the rear face of the module.

25. A module according to claim 24, wherein the ventilation unit is detachably mounted to the module.

26. A module according to claim 15, wherein the motherboard and daughter board occupy a volume extending between a portion of the front face of the module and a portion of the rear face of the module, and wherein substantially the entire area of the said portion of the front or rear face of the module is covered by an array of ventilation units.

27. A module according to claim 15, wherein the interior of the module is divided by a bulkhead extending between the front face and the rear face of the module.

28. A module according to claim 15, wherein the module is rack-mountable.

29. A method of removing a daughterboard from a module of a rack-mounted modular electronic circuit, comprising the steps of:
moving a module out of the rack in a forward or rearward horizontal direction;
withdrawing a daughterboard from the module through an opening in an upper, lower or side surface of the module.
